(19) United States
(12) Patent Application Publication
(10) Pub. No.: US 2025/0230356 A1
(43) Pub. Date: Jul. 17, 2025

(54) THINNER COMPOSITION

(71) Applicant: DONGWOO FINE-CHEM CO., LTD., Jeollabuk-do (KR)

(72) Inventors: TAE KYUNG LEE, Jeollabuk-do (KR); JEONG HYUN KIM, Jeollabuk-do (KR); SO MIN LEE, Jeollabuk-do (KR); JI MIN CHUN, Jeollabuk-do (KR); HAN WOO PARK, Jeollabuk-do (KR)

(21) Appl. No.: 19/020,009

(22) Filed: Jan. 14, 2025

(30) Foreign Application Priority Data
Jan. 16, 2024 (KR) 10-2024-0006846

(51) Int. Cl. C09K 13/00

(52) U.S. Cl. CPC C09K 13/00

(57) ABSTRACT

A thinner composition includes a multifunctional carboxylic acid compound, a first organic solvent having a dielectric constant of 35 or more, and a second organic solvent having a dielectric constant of less than 35. When including organic solvents having different dielectric constants together and the multifunctional carboxylic acid compound, an amount of the photoresist used may be reduced and thickness uniformity of the photosensitive film may be implemented.

### CROSS-REFERENCE TO RELATED APPLICATION AND CLAIM OF PRIORITY

This application claims the benefit under 35 USC § 119 of Korean Patent Application No. 10-2024-0006846, filed on Jan. 16, 2024, in the Korean Intellectual Property Office, the entire disclosure of which is incorporated by reference herein.

### BACKGROUND

### 1. Field of the Invention

The present invention relates to a thinner composition, and more specifically, to a thinner composition which includes organic solvents, and a substrate processing method using the thinner composition.

### 2. Description of the Related Art

In a semiconductor manufacturing process and a panel manufacturing process of a display device, an electronic circuit may be formed on a wafer through a photolithography process. For example, a photoresist layer may be formed on a wafer, followed by exposing and developing the photoresist layer to form a photoresist pattern thereon.

Among photolithography processes, a rotational application process supplies a photosensitive film to a wafer and rotates a substrate such that the photosensitive film evenly spread on the surface by a centrifugal force. However, the photosensitive films may be concentrated on an edge portion and a rear surface of the substrate due to the centrifugal force. This may cause damages to equipment and the wafer, such that a thinner composition is used to remove them.

Depending on a dissolution rate of the thinner composition, a difference in the smoothness of a cross-section of the wafer may occur. For example, if the dissolution rate is excessively high, attack for the photosensitive film may occur during rinse of the photosensitive film, and if the dissolution rate is excessively low, a tailing phenomenon may occur.

In addition, the thinner composition is required to have characteristic of easily evaporating after removing a photosensitive resin and not remaining on the surface of the substrate.

For example, if the volatility of the thinner composition is too low, the remaining thinner composition may act as a source of contamination in various processes, particularly in a subsequent etching process, thereby reducing a yield of the semiconductor device. For example, if the volatility of the thinner composition is too high, the substrate may be rapidly cooled, thereby resulting in a significant variation in the thickness of the applied photosensitive film.

Meanwhile, as a degree of integration of the semiconductor is increased recently, it is necessary for a film on the wafer to be formed with a uniform thickness. In this regard, Korean Patent Laid-Open Publication No. 2020-0025651 discloses a thinner composition including propionate, and Korean Patent Laid-Open Publication No. 2006-0005111 discloses a thinner composition including alkyl ethanoate.

However, a thinner composition capable of reducing an amount of the photoresist used and uniformly controlling the thickness of the film during photoresist coating has not been disclosed in the art including the above patents.

### SUMMARY

An object of the present invention is to provide a thinner composition which improves thickness uniformity of a photosensitive film.

Another object of the present invention is to provide a substrate processing method using the thinner composition which improves thickness uniformity of a photosensitive film.

To achieve the above objects, the following technical solutions are adopted in the present invention.
1. A thinner composition including: a multifunctional carboxylic acid compound; a first organic solvent having a dielectric constant of 35 or more; and a second organic solvent having a dielectric constant of less than 35.
2. The thinner composition according to the above 1, wherein the multifunctional carboxylic acid compound includes a compound to which two or more carboxyl groups are bonded.
3. The thinner composition according to the above 2, wherein the multifunctional carboxylic acid compound includes a compound to which carboxyl groups are bonded at both ends thereof.
4. The thinner composition according to the above 2, wherein the multifunctional carboxylic acid compound includes a carboxyl acid compound to which at least one substituent is bonded, and the substituent includes at least one selected from the group consisting of a hydroxyl group, a thiol group, a carboxyl group, a primary amine group, an alkylcarbonylamine group having 2 to 10 carbon atoms, an alkoxycarbonylamine group having 2 to 10 carbon atoms and an alkyl group having 1 to 6 carbon atoms.
5. The thinner composition according to the above 4, wherein the substituent includes a primary amine group or an alkoxycarbonylamine group having 2 to 10 carbon atoms.
6. The thinner composition according to the above 4, wherein the substituent is bonded to a carbon atom to which the carboxyl group is bonded, and the substituent is a primary amine group or an alkoxycarbonylamine group having 2 to 10 carbon atoms.
7. The thinner composition according to the above 1, wherein the multifunctional carboxylic acid compound includes a compound represented by Formula 1 below:

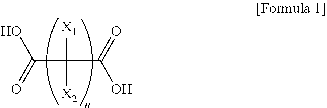

(in Formula 1 above, X₁ and X₂ are each independently hydrogen; a hydroxyl group; a thiol group; a carboxyl group; a primary amine group; an alkylcarbonylamine group having 2 to 10 carbon atoms; an alkoxycarbonylamine group having 2 to 10 carbon atoms; an alkyl group having 1 to 6 carbon atoms; or an alkyl group having 1 to 6 carbon atoms and substituted with at least one selected from the group consisting of a hydroxyl group, a thiol group, a primary amine group, a carboxyl group, an aldehyde group, an alkoxy group having 1 to 10 carbon atoms, an alkylcarbonyl group having 2 to 10 carbon atoms, and an alkoxycarbonyl group having 2 to 10 carbon atoms, wherein n is an integer of 1 to 10).
8. The thinner composition according to the above 7, wherein the X₁ and X₂ are each independently selected from the group consisting of hydrogen, a hydroxyl group and a carboxyl group.
9. The thinner composition according to the above 7, wherein one or more of X₁ and X₂ is a primary amine group, an alkylcarbonylamine group having 2 to 10 carbon atoms, or an alkoxycarbonylamine group having 2 to 10 carbon atoms.
10. The thinner composition according to the above 1, wherein the multifunctional carboxylic acid compound includes at least one selected from the group consisting of succinic acid, malic acid, citric acid, glutamic acid, and N-(tert-butoxycarbonyl)-L-aspartic acid.
11. The thinner composition according to the above 1, wherein the multifunctional carboxylic acid compound is included in an amount of 0.01 ppm to 100 ppm based on a total weight of the organic solvent including the first organic solvent and the second organic solvent.
12. The thinner composition according to the above 1, wherein the composition includes no monovalent carboxylic acid compound.
13. The thinner composition according to the above 1, wherein a content of the first organic solvent is a content of the second organic solvent or less based on a total weight of the organic solvent including the first organic solvent and the second organic solvent.
14. The thinner composition according to the above 1, wherein a content of the first organic solvent is 0.5 wt % to 50 wt %, and a content of the second organic solvent is 50 wt % to 99.5 wt %, based on a total weight of the organic solvent including the first organic solvent and the second organic solvent.
15. The thinner composition according to the above 1, wherein the first organic solvent includes at least one selected from the group consisting of dimethyl sulfate, gamma-buturolactone, ethylene carbonate, propylene carbonate, N,N-dimethylformamide, N,N-diethylformamide and N,N-dimethylacetamide, and the second organic solvent includes at least one selected from the group consisting of propylene glycol monoalkyl ether acetate, alkyl 2-hydroxyisobutyrate, propionate, ketone, and pyrrolidone.
16. A substrate processing method including treating the substrate with the thinner composition according to the above-described embodiments before applying a photoresist to the substrate.
17. A substrate processing method including treating a substrate with the thinner composition according to the above-described embodiments before an exposure process after applying a photoresist to the substrate.

The thinner composition according to exemplary embodiments of the present invention may include organic solvents having different dielectric constants together. When including the organic solvents together, uniformity of an edge bead removal (EBR) line may be implemented, while reducing an amount of the photoresist used.

According to exemplary embodiments, the thinner composition may include a multifunctional carboxylic acid compound. The multifunctional carboxylic acid may increase compatibility between the organic solvents. Therefore, reduction in the amount of the photoresist used and thickness uniformity of the photosensitive film may be implemented.

In some embodiments, the multifunctional carboxylic acid compound may include a compound to which two or more carboxyl groups are bonded. In some embodiments, the multifunctional carboxylic acid compound may include a compound to which a primary amine group or an alkoxycarbonylamine group having 2 to 10 carbon atoms is bonded. The compatibility between the organic solvents may be significantly improved by the structure of the multifunctional carboxylic acid compound. Therefore, the uniformity of the photosensitive film may be improved.

### DETAILED DESCRIPTION OF THE INVENTION

According to embodiments of the present invention, a thinner composition including a multifunctional carboxylic acid compound or a derivative thereof, a first organic solvent and a second organic solvent which have different dielectric constants is provided. In addition, according to embodiments of the present invention, a substrate processing method using the thinner composition is provided.

### <Organic Solvent>

The thinner composition according to exemplary embodiments may include a first organic solvent having a dielectric constant of 35 or more and a second organic solvent having a dielectric constant of less than 35.

The first organic solvent may include, for example, dimethyl sulfate, dimethylsulfone, diethylsulfone, methylsulfolane, sulfolane, gamma-buturolactone, delta-valerolactone, ethylene carbonate, propylene carbonate, vinylene carbonate, N,N-dimethylformamide, N,N-diethylformamide, N,N-dimethylacetamide, acetonitrile, ethylene glycol, diethylene glycol, glycerin and the like.

The first organic solvent may include a single solvent or a mixed solvent of the above-described solvents.

For example, the first organic solvent may remain on the wafer and widely spread the photoresist. Therefore, as the first organic solvent is included in the thinner composition, an amount of the photoresist used may be reduced. In addition, a photosensitive film may be formed without a stain on the surface or a portion to which the photoresist is not applied.

According to exemplary embodiments, the first organic solvent may include at least one selected from the group consisting of dimethyl sulfate, gamma butyrolactone, ethylene carbonate, propylene carbonate, N,N-dimethylformamide, N,N-diethylformamide and N,N-dimethylacetamide.

According to exemplary embodiments, a content of the first organic solvent may be a content of the second organic solvent or less to be described below, based on a total weight of the organic solvent including the first organic solvent and the second organic solvent.

When the content of the first organic solvent is the content of the second organic solvent or less, a resist reducing coating (RRC) process and an edge bead removal (EBR) process may be efficiently performed.

For example, if the content of the first organic solvent exceeds the content of the second organic solvent, efficiency of the EBR process may be decreased.

According to exemplary embodiments, the content of the first organic solvent may be 0.5% by weight (“wt %”) to 50 wt % based on a total weight of the thinner composition, specifically, based on the total weight of the organic solvent including the first organic solvent and the second organic solvent. In some embodiments, the content of the first organic solvent may be 1 wt % to 30 wt % or 2 wt % to 20 wt %.

When the content of the first organic solvent corresponds to the above range, the amount of the photoresist used may be reduced.

For example, if the content of the first organic solvent exceeds the above range, it may be greater than the content of the second organic solvent to be described below. Accordingly, efficiency of the EBR process and performance of removing the unnecessary photoresist may be decreased. For example, a hump height of the photosensitive film may be increased, thereby decreasing the uniformity, and the uniformity or straightness of the EBR line is not achieved or may be decreased.

For example, if the content of the first organic solvent is less than the above range, stains may occur or the portion to which the photoresist is not applied may be increased. Therefore, a reduction in the amount of the photoresist used may not be implemented.

According to exemplary embodiments, the second organic solvent may include alkyl alcohol, alkyl propionate, alkylene glycol monoalkyl ether, alkyl propionate, alkylene glycol monoalkyl ether acetate, alkyl 2-hydroxyisobutyrate, ketone, alkyl acetate and the like.

For example, the second organic solvent may include alcohols such as methanol, ethanol, propanol, isopropanol, butanol, isobutanol, t-butanol, pentanol, hexanol, heptanol, octanol, tetrahydrofurfuryl alcohol (THFA), etc.; alkylene glycol monoalkyl ethers such as ethylene glycol monomethyl ether, ethylene glycol monoethyl ether, ethylene glycol monoisopropyl ether, ethylene glycol monobutyl ether, diethylene glycol monomethyl ether, diethylene glycol monoethyl ether, diethylene glycol monoisopropyl ether, diethylene glycol monobutyl ether, triethylene glycol monomethyl ether, triethylene glycol monoethyl ether, triethylene glycol monoisopropyl ether, triethylene glycol monobutyl ether, polyethylene glycol monomethyl ether, polyethylene glycol monobutyl ether, propylene glycol monomethyl ether, dipropylene glycol monomethyl ether, tripropylene glycol monomethyl ether, etc.; propionates such as ethyl 3-methoxypropionate, propyl 3-methoxypropionate, butyl 3-methoxypropionate, ethyl 3-ethoxypropionate, propyl 3-ethoxypropionate, butyl 3-ethoxypropionate, ethyl 3-propoxypropionate, propyl 3-propoxypropionate, butyl 3-propoxypropionate, ethyl 3-butoxypropionate, propyl 3-butoxypropionate, butyl 3-butoxypropionate, etc.; alkylene glycol monoalkyl ether acetates such as propylene glycol monomethyl ether acetate, propylene glycol monoethyl ether acetate, ethylene glycol monomethyl ether acetate, ethylene glycol monoethyl ether acetate, etc.; alkyl 2-hydroxyisobutyrates such as methyl 2-hydroxyisobutyrate, ethyl 2-hydroxyisobutyrate, propyl 2-hydroxyisobutyrate, isopropyl 2-hydroxyisobutyrate, butyl 2-hydroxyisobutyrate, and tert-butyl 2-hydroxyisobutyrate, etc.; linear ketones such as acetone, methyl ethyl ketone, methyl propyl ketone, methyl butyl ketone, methyl pentyl ketone, methyl hexyl ketone, methyl hepyl ketone, methyl octyl ketone, ethyl propyl ketone, ethyl butyl ketone, ethyl pentyl ketone, etc.; cyclic ketones such as cyclopropanone, cyclobutanone, cyclopentanone, cyclohexanone, and cycloheptanone, etc.; pyrrolidones such as 2-pyrrolidone, n-methylpyrrolidone, n-ethylpyrrolidone, n-propylpyrrolidone, 1-hydroxyethyl-2-pyrrolidone, 1-hydroxypropyl-2-pyrrolidone, etc.

The second organic solvent may include a single solvent or a mixed solvent of the above-described solvents.

For example, the second organic solvent may remove the photoresist formed at an edge portion of the wafer. Therefore, as the second organic solvent is included in the thinner composition, an unnecessary photosensitive film may be removed. In addition, overall uniformity of the photosensitive film may be improved.

According to exemplary embodiments, the second organic solvent may include at least one selected from the group consisting of a propylene glycol monoalkyl ether acetate organic solvent, an alkyl 2-hydroxyisobutyrate organic solvent, a propionate organic solvent, a ketone organic solvent, and a pyrrolidone organic solvent.

According to exemplary embodiments, a content of the second organic solvent may be 50 wt % to 99.5 wt %, based on the total weight of the organic solvent including the first organic solvent and the second organic solvent. In some embodiments, the content of the second organic solvent may be 70 wt % to 99 wt % or 80 wt % to 98 wt %.

When the content of the second organic solvent corresponds to the above range, the uniformity of the photosensitive film may be secured. For example, the straightness and/or uniformity of the EBR line may be secured, and the hump height may be reduced.

According to exemplary embodiments, a weight ratio of the second organic solvent based on a weight of the first organic solvent may be 1 to 15. In some embodiments, the weight ratio of the second organic solvent based on the weight of the first organic solvent may be 1 to 12, 1 to 9.

When the weight ratio of the second organic solvent to the first organic solvent corresponds to the above range, the amount of the photoresist used may be reduced, and the thickness uniformity of the photosensitive film may be secured.

### <Multifunctional Carboxylic Acid Compound or Derivative Thereof>

As used herein, the “alkyl” includes a straight-chain hydrocarbon and a branched-chain hydrocarbon. For example, alkyl having 4 carbon atoms may include n-butyl, isobutyl, sec-butyl and tert-butyl.

As used herein, the “alkylcarbonylamine group” may refer to a structure in which alkyl, carbonyl and an amine group are sequentially bonded. For example, the alkylcarbonylamine group may be expressed as −NH—C(═O)—R (wherein, R is an alkyl group).

As used herein, the “alkoxycarbonylamine group” may refer to a structure in which alkoxy, carbonyl and an amine group are sequentially bonded. For example, the alkoxycarbonylamine group may be expressed as −NH—C(═O)—OR (wherein, R is an alkyl group).

The thinner composition according to exemplary embodiments may include a multifunctional carboxylic acid compound or a derivative thereof.

According to exemplary embodiments, the multifunctional carboxylic acid compound may include a compound to which two or more carboxyl groups are bonded.

For example, the multifunctional carboxylic acid compound may include a compound having a structure in which two or more carboxyl groups are bonded to a hydrocarbon chain independent of positions to which the carboxyl groups are bonded. The compound including two or more carboxyl groups may increase the compatibility between a resin and the organic solvent, and thus may improve the thickness uniformity of the photosensitive film.

For example, when including a monovalent carboxylic acid compound to which one carboxyl group is bonded instead of the multifunctional carboxylic acid compound, the thickness uniformity of the photosensitive film may be decreased.

According to exemplary embodiments, the thinner composition may include no monovalent carboxylic acid compound. For example, the monovalent carboxylic acid may include an alkyl carboxylic acid such as a propionic acid, butyric acid, isobutyric acid, pentanoic acid, hexanoic acid, heptanoic acid, etc.; an alkyl carboxylic acid to which a substituent other than the carboxyl group is bonded; an amino acid to which one carboxyl group such as alanine, valine, leucine, isoleucine, methionine, cysteine is bonded, etc.

For example, when further including the monovalent carboxylic acid compound, the thickness uniformity of the photosensitive film may rather be decreased.

According to exemplary embodiments, the multifunctional carboxylic acid compound may include a compound to which carboxyl groups are bonded at both ends thereof.

For example, the multifunctional carboxylic acid compound may include a compound having a structure of (COOH)—(CH₂)ₐ—(COOH) (wherein, a is an integer of 1 to 20).

According to exemplary embodiments, the multifunctional carboxylic acid compound may include a compound to which carboxyl groups are bonded at both ends of a hydrocarbon chain, and the hydrocarbon chain may include a straight chain and a branched chain.

For example, the multifunctional carboxylic acid compound may include a compound having a structure of (COOH)—(CH₂)₂—(CH(CH₃))—(COOH).

In some embodiments, the multifunctional carboxylic acid compound may include a compound to which three or more carboxyl groups are bonded.

According to exemplary embodiments, the multifunctional carboxylic acid compound may include a carboxylic acid compound to which at least one substituent is bonded.

For example, the substituent may be bonded to the hydrocarbon chain of the multifunctional carboxylic acid compound.

The substituent may include a protective group including a hydroxyl group; a thiol group; a carboxyl group; a primary amine group; an alkyl carbonyl group having 2 to 10 carbon atoms; an alkenyl carbonyl group having 3 to 10 carbon atoms; an alkoxy group having 1 to 6 carbon atoms; an alkylcarbonylamine group having 2 to 10 carbon atoms; an alkoxycarbonylamine group having 2 to 10 carbon atoms; an alkyl group having 1 to 6 carbon atoms; or an alkyl group having 1 to 6 carbon atoms and substituted with at least one selected from the group consisting of a hydroxyl group, a thiol group, a primary amine group, a carboxyl group, an aldehyde group, an alkoxy group having 1 to 10 carbon atoms, an alkylcarbonyl group having 2 to 10 carbon atoms, and an alkoxycarbonyl group having 2 to 10 carbon atoms; an allyl group, a benzyl group, an acetyl group, a benzoyl group, etc.

In some embodiments, the multifunctional carboxylic acid compound may include a nitrogen atom within the compound structure. For example, the nitrogen atom may be included in the substituent thus to be included in the multifunctional carboxylic acid compound.

According to exemplary embodiments, the substituent may include at least one selected from the group consisting of a hydroxyl group, a thiol group, a carboxyl group, a primary amine group, an alkylcarbonylamine group having 2 to 10 carbon atoms, an alkoxycarbonylamine group having 2 to 10 carbon atoms and an alkyl group having 1 to 6 carbon atoms.

In some embodiments, the substituent may include at least one selected from the group consisting of a hydroxyl group, a carboxyl group, a primary amine group, and an alkoxycarbonylamine group having 2 to 10 carbon atoms.

In some embodiments, the substituent may include a primary amine group or an alkoxycarbonylamine group having 2 to 10 carbon atoms.

In some embodiments, the substituent may be bonded to a carbon atom to which the carboxyl group is not bonded. For example, the multifunctional carboxylic acid compound may include a compound including a hydrocarbon chain having 3 to 12 carbon atoms, to which carboxyl groups are bonded at both ends of a hydrocarbon chain, and a substituent may be bonded to a portion of the hydrocarbon chain to which the carboxyl group is not bonded.

In some embodiments, the substituent may be bonded to a carbon atom to which the carboxyl group is bonded. For example, the multifunctional carboxylic acid compound may include a compound including a hydrocarbon chain having 2 to 12 carbon atoms, to which carboxyl groups are bonded to both ends of the hydrocarbon chain, and a substituent may be bonded to at least one carbon atom of the both ends.

In some embodiments, the substituent may be bonded to a carbon atom to which the carboxyl group is bonded, and the substituent may be a primary amine group or an alkoxycarbonylamine group having 2 to 10 carbon atoms.

In some embodiments, the multifunctional carboxylic acid compound may include an amino acid or an amino acid derivative. For example, an amino acid may be expressed by the substituent of the multifunctional carboxylic acid compound including the substituent. For example, the type and bonding position of the substituent may be adjusted to express the amino acid.

In some embodiments, the amino acid may include an aspartic acid or glutamic acid.

The multifunctional carboxylic acid compound may include an amino acid or an amino acid derivative, such that the thickness uniformity of the photosensitive film may be improved. For example, the compatibility between the organic solvents may be increased by the amphoteric amino acid, thereby improving the thickness uniformity of the photosensitive film.

According to exemplary embodiments, the multifunctional carboxylic acid compound may include a compound represented by Formula 1 below.

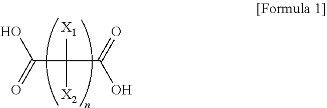

In Formula 1 above, X₁ and X₂ are each independently hydrogen; a hydroxyl group; a thiol group; a carboxyl group; a primary amine group; an alkylcarbonylamine group having 2 to 10 carbon atoms; an alkoxycarbonylamine group having 2 to 10 carbon atoms; an alkyl group having 1 to 6 carbon atoms; or an alkyl group having 1 to 6 carbon atoms and substituted with at least one selected from the group consisting of a hydroxyl group, a thiol group, a primary amine group, a carboxyl group, an aldehyde group, an alkoxy group having 1 to 10 carbon atoms, an alkylcarbonyl group having 2 to 10 carbon atoms, and an alkoxycarbonyl group having 2 to 10 carbon atoms.

In Formula 1 above, n is an integer of 1 to 10.

According to exemplary embodiments, the X₁ and X₂ may each be independently selected from the group consisting of hydrogen, a hydroxyl group and a carboxyl group.

In some embodiments, the X₁ and X₂ are hydrogen.

In some embodiments, one or more of the X₁ and X₂ is a hydroxyl group.

In some embodiments, one or more of the X₁ and X₂ is a carboxyl group.

In some embodiments, X₁ is a hydroxyl group, and X₂ is a carboxyl group.

According to exemplary embodiments, one or more of X₁ and X₂ is a primary amine group, an alkylcarbonylamine group having 2 to 10 carbon atoms, or an alkoxycarbonylamine group having 2 to 10 carbon atoms.

In some embodiments, one or more of X₁ and X₂ is a primary amine group.

In some embodiments, one or more of X₁ and X₂ is an alkoxycarbonylamine group having 2 to 10 carbon atoms.

When n is an integer of 2 or more, each of X₁ and X₂ may be independently selected.

For example, when n is an integer 2 or more, Exemplary Structural Formula 1 below may be included. In the structural formula below, X₁′ and X₂′ are the same as defined in X₁ and X₂, respectively, and X₁, X₂, X₁′ and X₂′ may be independently selected.

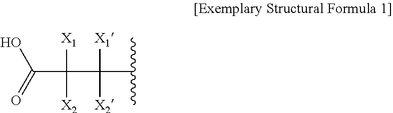

According to exemplary embodiments, the compound represented by Exemplary Structural Formula 1 above may include compounds represented by Formulas 2 to 4 below.

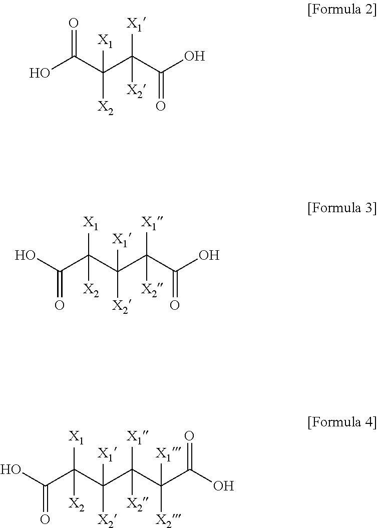

In Formulas 2 to 4 above, the X₁ and X₂ are the same as defined in the X₁ and X₂ of Formula 1 above.

The X₁′, X₂′, X₁″, X₂″, X₁′″ and X₂′″ are the same as defined in the X₁ and X₂, respectively.

According to exemplary embodiments, in Formula 2 above, X₁, X₂, X₁′ and X₂′ may each be independently selected from the group consisting of hydrogen, a hydroxyl group and a carboxyl group.

In some embodiments, in Formula 2 above, X₁, X₂, X₁′ and X₂′ may be hydrogen.

In some embodiments, in Formula 2 above, one or more of X₁, X₂, X₁′ and X₂′ may be a hydroxyl group.

In some embodiments, in Formula 2 above, one or more of X₁, X₂, X₁′ and X₂′ may be a primary amine group or an alkoxycarbonylamine group having 2 to 10 carbon atoms.

In some embodiments, in Formula 3 above, X₁, X₂, X₁″ and X₂″ are hydrogen, and X₁′ and X₂′ may each be independently selected from the group consisting of hydrogen, a hydroxyl group and a carboxyl group.

In some embodiments, in Formula 3 above, X₁, X₂, X₁″ and X₂″ are hydrogen, and X₁′ and X₂′ may each be independently selected from the group consisting of a hydroxyl group and a carboxyl group.

In some embodiments, in Formula 3 above, X₁′ and X₂′ are hydrogen, and one or more of X₁, X₂, X₁″ and X₂″ may be a primary amine group or an alkoxycarbonylamine group having 2 to 10 carbon atoms.

In some embodiments, in Formula 3 above, X₁′ and X₂′ are hydrogen, and one or more of X₁, X₂, X₁″ and X₂″ may be a primary amine group.

According to exemplary embodiments, a content of the multifunctional carboxylic acid compound may be 0.01 ppm to 100 ppm based on the total weight of the thinner composition. In some embodiments, the content of the multifunctional carboxylic acid compound may be 0.05 ppm to 100 ppm, 0.1 ppm to 100 ppm, 0.1 ppm to 30 ppm, or 0.1 ppm to 10 ppm based on the total weight of the thinner composition.

When the content of the multifunctional carboxylic acid compound corresponds to the above range, the thickness uniformity of the photosensitive film may be improved.

For example, if the content of the multifunctional carboxylic acid compound exceeds the above range, the multifunctional carboxylic acid compound may be precipitated without being dissolved, thereby inhibiting the uniformity of the photosensitive film.

For example, if the content of the multifunctional carboxylic acid compound is less than the above range, a desired change in the film uniformity may not be implemented.

### <Substrate Processing Method>

In addition, a method of treating a substrate with the thinner composition according to exemplary embodiments of the present invention is provided.

The substrate processing method includes steps of treating a substrate with the thinner composition and applying a photoresist to the substrate.

By applying the photoresist after treating the substrate with the thinner composition, a small amount of photoresist may be applied to the substrate. Therefore, process efficiency may be improved.

In addition, the substrate processing method of the present invention may further include a step of treating the substrate with the thinner composition before an exposure process (photolithography).

For example, the substrate is treated with the thinner composition, photoresist is applied to the substrate treated with the thinner composition, and the substrate may be treated with the thinner composition before an exposure process of the substrate on which the photoresist is applied.

By treating with the thinner composition before the exposure process, the unnecessary photoresist applied to an edge portion of the substrate may be efficiently removed.

The substrate processing method according to the present invention may be applied without limitation to a product in which the photoresist is used, for example, a method for manufacturing an electronic device. For example, it may be applied to a method for manufacturing a semiconductor device or a thin film transistor liquid crystal display device.

Hereinafter, experimental examples including specific examples and comparative examples will be described to more concretely understand the present invention. However, those skilled in the art will appreciate that such examples are provided for illustrative purposes and do not limit subject matters to be protected as disclosed in appended claims. Therefore, it will be apparent to those skilled in the art various alterations and modifications of the examples are possible within the scope and spirit of the present invention and duly included within the range as defined by the appended claims.

### EXAMPLES AND COMPARATIVE EXAMPLES

Thinner compositions having the components and contents described in Table 1 below were prepared.

TABLE 1

| | First organic | | Second organic | | Divalent carboxylic | | Monovalent | |
|---|---|---|---|---|---|---|---|---|
| | solvent (A) | | solvent (B) | | acid (C) | | carboxylic acid (D) | |
| | | Content | | Content | | Content | | Content |
| Division | Component | (wt parts) | Component | (wt parts) | Component | (ppm) | Component | (ppm) |
| Example 1 | A-1 | 10 | B-1 | 90 | C-5 | 10 | — | — |
| Example 2 | A-2 | 10 | B-1 | 90 | C-5 | 10 | — | — |
| Example 3 | A-3 | 10 | B-1 | 90 | C-5 | 10 | — | — |
| Example 4 | A-4 | 10 | B-1 | 90 | C-5 | 10 | — | — |
| Example 5 | A-2 | 10 | B-2 | 90 | C-5 | 10 | — | — |
| Example 6 | A-2 | 10 | B-3 | 90 | C-5 | 10 | — | — |
| Example 7 | A-2 | 10 | B-4 | 90 | C-5 | 10 | — | — |
| Example 8 | A-2 | 10 | B-5 | 90 | C-5 | 10 | — | — |
| Example 9 | A-2 | 10 | B-1 | 90 | C-4 | 10 | — | — |
| Example 10 | A-2 | 10 | B-1 | 90 | C-3 | 10 | — | — |
| Example 11 | A-2 | 10 | B-1 | 90 | C-2 | 10 | — | — |
| Example 12 | A-2 | 10 | B-1 | 90 | C-1 | 10 | — | — |
| Example 13 | A-2 | 0.1 | B-1 | 99.9 | C-5 | 10 | — | — |
| Example 14 | A-2 | 50 | B-1 | 50 | C-5 | 10 | — | — |
| Example 15 | A-2 | 10 | B-1 | 90 | C-5 | 0.01 | — | — |
| Example 16 | A-2 | 10 | B-1 | 90 | C-5 | 0.1 | — | — |
| Example 17 | A-2 | 10 | B-1 | 90 | C-5 | 100 | — | — |
| Example 18 | A-2 | 0.05 | B-1 | 99.95 | C-5 | 10 | — | — |
| Example 19 | A-2 | 51 | B-1 | 49 | C-5 | 10 | — | — |
| Example 20 | A-2 | 10 | B-1 | 90 | C-5 | 110 | — | — |
| Comparative | A-2 | 10 | B-1 | 90 | — | — | D-1 | 10 |
| Example 1 | | | | | | | | |
| Comparative | A-2 | 10 | B-1 | 90 | — | — | D-2 | 10 |
| Example 2 | | | | | | | | |
| Comparative | A-2 | 10 | B-1 | 90 | — | — | D-3 | 10 |
| Example 3 | | | | | | | | |
| Comparative | A-2 | 10 | B-1 | 90 | — | — | — | — |
| Example 4 | | | | | | | | |
| Comparative | A-2 | 100 | — | — | — | — | — | — |
| Example 5 | | | | | | | | |
| Comparative | — | — | B-1 | 100 | — | — | — | — |
| Example 6 | | | | | | | | |
| Comparative | A-2 | 100 | — | — | C-5 | 10 | — | — |
| Example 7 | | | | | | | | |
| Comparative | — | — | B-1 | 100 | C-5 | 10 | — | — |
| Example 8 | | | | | | | | |

(A): First organic solvent
A-1: Dimethyl sulfate (ε = 46.7)
A-2: Gamma-buturolactone (ε = 40.2)
A-3: Propylene carbonate (ε = 64.4)
A-4: N,N-dimethylformamide (ε = 36.7)
(B): Second organic solvent
B-1: Propylene glycol monomethyl ether acetate (ε = 8.3)
B-2: Cyclopentanone (ε = 14.5)
B-3: N-methyl-2-pyrrolidone (ε = 32.2)
B-4: Ethyl 3-ethoxy propionate (ε = 3.1)
B-5: Methyl 2-hydroxy isobutyrate (ε = 12.3)
(C): Divalent carboxylic acid
C-1: Succinic acid
C-2: Malic acid
C-3: Citric acid
C-4: Glutamic acid
C-5: N-(tert-butoxycarbonyl)-L-aspartic acid
(D): Monovalent carboxylic acid
D-1: Heptanoic acid
D-2: Alanine
D-3: 3-hydroxypropionic acid

### Experimental Example 1. Evaluation of RRC (Reducing Resist Coating) Performance

The RRC performance of four photoresists (PR1 to PR4) described in Table 2 was tested.

Specifically, before applying the photoresist to a 12-inch silicon wafer, 4.0 cc of each thinner composition according to the examples and comparative examples was applied to the wafer for 3 seconds in a stationary state under the conditions listed in Table 3 below. Thereafter, the wafer was rotated at 2,000 rpm for 5 seconds to distribute the thinner composition over the entire surface of an upper portion of the wafer, and 0.8 cc and 0.6 cc of the four photoresists were applied thereto, respectively.

Standards for evaluation are as follows, and evaluation results are shown in Tables 4 to 7.

### <Standards for RRC Evaluation>

⊚: As a result of RRC, when applying photoresist after thinner is applied to a 12-inch wafer, 95% or more of the photoresist is applied to the wafer and there are no stains
∘: As a result of RRC, when applying photoresist after thinner is applied to a 12-inch wafer, 95% or more of the photoresist is applied to the wafer, but there are stains or portions to which the photoresist is not applied

Δ: As a result of RRC, when applying photoresist after thinner is applied to a 12-inch wafer, 80 to 95% of the photoresist is applied to the wafer

X: As a result of RRC, when applying the photoresist after applying thinner on a 12-inch wafer, less than 80% of the photoresist is applied to the wafer

TABLE 2

| Division | PR type |
|---|---|
| PR 1 | NTD PR A for EUV |
| PR 2 | NTD PR B for EUV |
| PR 3 | PR C for ArF |
| PR 4 | PR D for KrF |

TABLE 3

| | | | Rotation | |
|---|---|---|---|---|
| | | Time | speed | |
| Step | | (sec) | (rpm) | Note |
| 1 | Thinner | 3 | 0 | Thinner application |
| | application | | | amount: 4.0 cc |
| 2 | Thinner coating | 5 | 2,000 | — |
| 3 | PR injection | 5 | 500 | PR application amount: |
| | condition | | | 0.5 cc to 4 cc |
| 4 | PR coating | 20 | 500 to 2,000 | Adjust film thickness |
| | | | | according to purpose of |
| | | | | each type of PR |
| 5 | EBR Condition | 9 | 800 | Thinner injection |
| | | | | speed: 15 mL/min |
| 6 | Soft baking | 50 to 60 | — | Temperature according |
| | | | | to PR: 90 to 130° C. |

### Experimental Example 2. Unnecessary Photosensitive Film Removal Experiment (Edge Bead Removal (EBR) Experiment)

The EBR performance was tested for the four types of photoresists (PR1 to PR4) described in Table 2.

Specifically, the four types of photoresists (PR1 to PR4) described in Table 2 were applied to a 12-inch silicon wafer, and then each thinner composition according to the examples and comparative examples was applied to the entire surface of the upper portion of the wafer under the conditions listed in Table 3 to form a photosensitive film coated thereon. Thereafter, an EBR experiment was conducted to remove the unnecessary photosensitive film at the edge portion under the conditions listed in Step 5 of Table 3.

Each thinner composition according to the examples and comparative examples was supplied from a pressure vessel equipped with a pressure gauge, and a total of 2.2 cc of the thinner composition was injected through an EBR nozzle.

The straightness, uniformity, and tailing phenomenon of the EBR line were investigated using an optical microscope at a magnification of 400× and 1,000×, and the performance of removing the unnecessary photosensitive film was evaluated. In addition, the hump height was measured using a film thickness measuring device (Dektak, Bruker). Specifically, the film thickness of 35 μm inside and 35 μm outside the wafer was measured based on the EBR line of the photosensitive film, and the hump height was calculated from a difference between a maximum film thickness value and an average thickness of the photosensitive film.

Standards for evaluation are as follows, and evaluation results are shown in Tables 4 to 7.

### <Standards for EBR Evaluation>

⊚: Constant straightness and uniformity of the EBR line on the photosensitive film after EBR are observed
∘: The straightness of the EBR line on the photosensitive film after EBR is observed, but uniformity is not observed
Δ: The straightness and uniformity of the EBR line on the photosensitive film after EBR are not observed
X: The uniformity of the EBR line on the photosensitive film after EBR is not observed, and a tailing phenomenon occurs

### <Standards for Hump Height Evaluation>

⊚: When the hump height is less than 100 Å
∘: When the hump height is 100 Å or more but less than 500 Å
Δ: When the hump height is 500 Å or more but less than 1,000 Å
X: When the hump height is 1,000 Å or more

### Experimental Example 3. Evaluation of Coating Uniformity

For the four types of photoresists (PR1 to PR4) described in Table 2, film thicknesses at 61 points on an upper surface of the wafer were measured, and the standard deviation was calculated to evaluate the coating uniformity.

Specifically, before applying the photoresist to a 12-inch silicon wafer, 4.0 cc of each thinner composition according to the examples and comparative examples was applied the wafer for 3 seconds in a stationary state under the conditions listed in Table 3. The wafer was rotated at 2,000 rpm for 5 seconds to distribute the thinner over the entire upper surface of the wafer, and 1.0 cc of each of the four types of photoresists was applied thereto.

Standards for evaluation are as follows, and evaluation results are shown in Tables 4 to 7.

### <Standards for Uniformity Evaluation>

⊚: When the standard deviation (Ò) value for the PR film thickness of 61 points is less than 20 Å
∘: When the standard deviation (Ò) value for the PR film thickness of 61 points is 20 Å or more but less than 50 Å
Δ: When the standard deviation (Ò) value for the PR film thickness of 61 points is 50 Å or more but less than 100 Å
X: When the standard deviation (Ò) value for the PR film thickness of 61 points is 100 Å or more

TABLE 4

| | PR 1 | | | | |
|---|---|---|---|---|---|
| | RRC | RRC | | Hump | |
| Division | (0.8 cc) | (0.6 cc) | EBR | height | Uniformity |
| Example 1 | ⊚ | ⊚ | ◯ | ◯ | ⊚ |
| Example 2 | ⊚ | ⊚ | ⊚ | ⊚ | ⊚ |
| Example 3 | ⊚ | ⊚ | ⊚ | ⊚ | ⊚ |
| Example 4 | ⊚ | ⊚ | ◯ | ◯ | ⊚ |
| Example 5 | ⊚ | ⊚ | ◯ | ◯ | ⊚ |
| Example 6 | ⊚ | ⊚ | ◯ | ◯ | ⊚ |
| Example 7 | ⊚ | ⊚ | ⊚ | ⊚ | ⊚ |
| Example 8 | ⊚ | ⊚ | ◯ | ◯ | ⊚ |
| Example 9 | ⊚ | ⊚ | ⊚ | ⊚ | ⊚ |
| Example 10 | ⊚ | ⊚ | ⊚ | ⊚ | ◯ |
| Example 11 | ⊚ | ⊚ | ⊚ | ⊚ | ◯ |
| Example 12 | ⊚ | ⊚ | ⊚ | ⊚ | ◯ |
| Example 13 | ⊚ | ◯ | ⊚ | ⊚ | ⊚ |
| Example 14 | ⊚ | ⊚ | ◯ | ◯ | ⊚ |
| Example 15 | ⊚ | ⊚ | ⊚ | ⊚ | ◯ |
| Example 16 | ⊚ | ⊚ | ⊚ | ⊚ | ⊚ |
| Example 17 | ⊚ | ⊚ | ⊚ | ⊚ | ◯ |
| Example 18 | ◯ | Δ | ⊚ | ⊚ | ◯ |
| Example 19 | ⊚ | ⊚ | Δ | Δ | ◯ |
| Example 20 | ⊚ | ⊚ | ⊚ | ⊚ | Δ |
| Comparative | ⊚ | ⊚ | ◯ | ◯ | X |
| Example 1 | | | | | |
| Comparative | ⊚ | ⊚ | ◯ | ◯ | X |
| Example 2 | | | | | |
| Comparative | ⊚ | ⊚ | ◯ | ◯ | X |
| Example 3 | | | | | |
| Comparative | ⊚ | ⊚ | ⊚ | ⊚ | Δ |
| Example 4 | | | | | |
| Comparative | ⊚ | ⊚ | Δ | Δ | Δ |
| Example 5 | | | | | |
| Comparative | Δ | X | ◯ | ◯ | Δ |
| Example 6 | | | | | |
| Comparative | ⊚ | ⊚ | Δ | Δ | ◯ |
| Example 7 | | | | | |
| Comparative | Δ | X | ◯ | ◯ | ◯ |
| Example 8 | | | | | |

TABLE 5

| | PR 2 | | | | |
|---|---|---|---|---|---|
| | RRC | RRC | | Hump | |
| Division | (0.8 cc) | (0.6 cc) | EBR | height | Uniformity |
| Example 1 | ⊚ | ⊚ | ◯ | ◯ | ⊚ |
| Example 2 | ⊚ | ⊚ | ⊚ | ⊚ | ⊚ |
| Example 3 | ⊚ | ⊚ | ⊚ | ⊚ | ⊚ |
| Example 4 | ⊚ | ⊚ | ◯ | ◯ | ⊚ |
| Example 5 | ⊚ | ⊚ | ◯ | ◯ | ⊚ |
| Example 6 | ⊚ | ⊚ | ◯ | ◯ | ⊚ |
| Example 7 | ⊚ | ⊚ | ⊚ | ⊚ | ⊚ |
| Example 8 | ⊚ | ⊚ | ◯ | ◯ | ⊚ |
| Example 9 | ⊚ | ⊚ | ⊚ | ⊚ | ⊚ |
| Example 10 | ⊚ | ⊚ | ⊚ | ⊚ | ◯ |
| Example 11 | ⊚ | ⊚ | ⊚ | ⊚ | ◯ |
| Example 12 | ⊚ | ⊚ | ⊚ | ⊚ | ◯ |
| Example 13 | ⊚ | ◯ | ⊚ | ⊚ | ⊚ |
| Example 14 | ⊚ | ⊚ | ◯ | ◯ | ⊚ |
| Example 15 | ⊚ | ⊚ | ⊚ | ⊚ | ◯ |
| Example 16 | ⊚ | ⊚ | ⊚ | ⊚ | ⊚ |
| Example 17 | ⊚ | ⊚ | ◯ | ◯ | ◯ |
| Example 18 | ◯ | Δ | ⊚ | ⊚ | ◯ |
| Example 19 | ⊚ | ⊚ | Δ | Δ | ◯ |
| Example 20 | ⊚ | ⊚ | ⊚ | ⊚ | Δ |
| Comparative | ⊚ | ⊚ | ◯ | ◯ | X |
| Example 1 | | | | | |
| Comparative | ⊚ | ⊚ | ◯ | ◯ | X |
| Example 2 | | | | | |
| Comparative | ⊚ | ⊚ | ◯ | ◯ | X |
| Example 3 | | | | | |
| Comparative | ⊚ | ⊚ | ⊚ | ⊚ | Δ |
| Example 4 | | | | | |
| Comparative | ⊚ | ⊚ | Δ | Δ | Δ |
| Example 5 | | | | | |
| Comparative | ◯ | Δ | ◯ | ◯ | Δ |
| Example 6 | | | | | |
| Comparative | ⊚ | ⊚ | Δ | Δ | ◯ |
| Example 7 | | | | | |
| Comparative | ◯ | Δ | ◯ | ◯ | ◯ |
| Example 8 | | | | | |

TABLE 6

| | PR 3 | | | | |
|---|---|---|---|---|---|
| | RRC | RRC | | Hump | |
| Division | (0.8 cc) | (0.6 cc) | EBR | height | Uniformity |
| Example 1 | ⊚ | ⊚ | ◯ | ◯ | ⊚ |
| Example 2 | ⊚ | ⊚ | ◯ | ◯ | ⊚ |
| Example 3 | ⊚ | ⊚ | ◯ | ◯ | ⊚ |
| Example 4 | ⊚ | ⊚ | ⊚ | ⊚ | ⊚ |
| Example 5 | ⊚ | ⊚ | ◯ | ◯ | ⊚ |
| Example 6 | ⊚ | ⊚ | ◯ | ◯ | ⊚ |
| Example 7 | ⊚ | ⊚ | ⊚ | ⊚ | ⊚ |
| Example 8 | ⊚ | ⊚ | ⊚ | ⊚ | ⊚ |
| Example 9 | ⊚ | ⊚ | ◯ | ◯ | ⊚ |
| Example 10 | ⊚ | ⊚ | ◯ | ◯ | ◯ |
| Example 11 | ⊚ | ⊚ | ◯ | ◯ | ◯ |
| Example 12 | ⊚ | ⊚ | ◯ | ◯ | ◯ |
| Example 13 | ⊚ | ◯ | ◯ | ◯ | ⊚ |
| Example 14 | ⊚ | ⊚ | ◯ | ◯ | ⊚ |
| Example 15 | ⊚ | ⊚ | ◯ | ◯ | ◯ |
| Example 16 | ⊚ | ⊚ | ◯ | ◯ | ⊚ |
| Example 17 | ⊚ | ⊚ | ◯ | ◯ | ◯ |
| Example 18 | ◯ | Δ | ◯ | ◯ | ◯ |
| Example 19 | ⊚ | ⊚ | Δ | Δ | ◯ |
| Example 20 | ⊚ | ⊚ | ◯ | ◯ | Δ |
| Comparative | ⊚ | ⊚ | Δ | Δ | X |
| Example 1 | | | | | |
| Comparative | ⊚ | ⊚ | Δ | Δ | X |
| Example 2 | | | | | |
| Comparative | ⊚ | ⊚ | Δ | Δ | X |
| Example 3 | | | | | |
| Comparative | ⊚ | ⊚ | ◯ | ◯ | Δ |
| Example 4 | | | | | |
| Comparative | ⊚ | ⊚ | Δ | Δ | Δ |
| Example 5 | | | | | |
| Comparative | ◯ | Δ | ◯ | ◯ | Δ |
| Example 6 | | | | | |
| Comparative | ⊚ | ⊚ | Δ | Δ | ◯ |
| Example 7 | | | | | |
| Comparative | ◯ | Δ | ◯ | ◯ | ◯ |
| Example 8 | | | | | |

TABLE 7

| | PR 4 | | | | |
|---|---|---|---|---|---|
| | RRC | RRC | | Hump | |
| Division | (0.8 cc) | (0.6 cc) | EBR | height | Uniformity |
| Example 1 | ⊚ | ⊚ | ⊚ | ⊚ | ⊚ |
| Example 2 | ⊚ | ⊚ | ◯ | ◯ | ⊚ |
| Example 3 | ⊚ | ⊚ | ◯ | ◯ | ⊚ |
| Example 4 | ⊚ | ⊚ | ◯ | ◯ | ⊚ |
| Example 5 | ⊚ | ⊚ | ◯ | ◯ | ⊚ |
| Example 6 | ⊚ | ⊚ | ◯ | ◯ | ⊚ |
| Example 7 | ⊚ | ⊚ | ⊚ | ⊚ | ⊚ |
| Example 8 | ⊚ | ⊚ | ◯ | ◯ | ⊚ |
| Example 9 | ⊚ | ⊚ | ◯ | ◯ | ⊚ |
| Example 10 | ⊚ | ⊚ | ◯ | ◯ | ◯ |
| Example 11 | ⊚ | ⊚ | ◯ | ◯ | ◯ |
| Example 12 | ⊚ | ⊚ | ◯ | ◯ | ◯ |
| Example 13 | ◯ | Δ | ◯ | ◯ | ⊚ |
| Example 14 | ⊚ | ⊚ | ◯ | ◯ | ⊚ |
| Example 15 | ⊚ | ⊚ | ◯ | ◯ | ◯ |
| Example 16 | ⊚ | ⊚ | ◯ | ◯ | ⊚ |
| Example 17 | ⊚ | ⊚ | ◯ | ◯ | ◯ |
| Example 18 | Δ | Δ | ◯ | ◯ | ◯ |
| Example 19 | ⊚ | ⊚ | Δ | Δ | ◯ |
| Example 20 | ⊚ | ⊚ | ◯ | ◯ | Δ |
| Comparative | ⊚ | ⊚ | Δ | Δ | X |
| Example 1 | | | | | |
| Comparative | ⊚ | ⊚ | Δ | Δ | X |
| Example 2 | | | | | |
| Comparative | ⊚ | ⊚ | Δ | Δ | X |
| Example 3 | | | | | |
| Comparative | ⊚ | ⊚ | ◯ | ◯ | Δ |
| Example 4 | | | | | |
| Comparative | ⊚ | ⊚ | Δ | Δ | Δ |
| Example 5 | | | | | |
| Comparative | Δ | X | ◯ | ◯ | Δ |
| Example 6 | | | | | |
| Comparative | ⊚ | ⊚ | Δ | Δ | ◯ |
| Example 7 | | | | | |
| Comparative | Δ | X | ◯ | ◯ | ◯ |
| Example 8 | | | | | |

Referring to Tables 4 to 7, when using the thinner compositions according to the examples of the present invention, it was exhibited that the photosensitive film was applied to the wafer by 95% or more, and there were no stains. In addition, there was no case where both the straightness and uniformity of the EBR line were not observed, and there was no case where the hump height calculation value was 500 Å or more. In addition, the standard deviation value was less than 50 Å.

In the case of the examples including an amino acid or a derivative thereof, a divalent carboxylic acid (C-4, C-5), by including an amine group, the standard deviation value was less than 20 Å regardless of the type of the photoresist.

In the case of Examples 13 and 18, where the content of the first organic solvent was small, there were cases where the photosensitive film was applied to the wafer by less than 95%, or there were no stains or portions to which the photoresist was not applied.

In the case of Example 19, where the content of the first organic solvent was greater than that of the second organic solvent, neither the straightness nor the uniformity of the EBR line was observed, and the hump height calculation value was 500 Å or more.

In the case of Example 20, where the content of the divalent carboxylic acid exceeded 100 ppm, the standard deviation value was 50 Å or more.

In the case of Comparative Examples 1 to 3, where the monovalent carboxylic acid was included instead of the divalent carboxylic acid, both the straightness and the uniformity of the EBR line were not observed, and there were cases where the hump height calculation value was 500 Å or more, depending on the type of the photoresist. In addition, the standard deviation value was 100 Å or more, regardless of the type of the photoresist.

In Comparative Examples 4 to 6 which did not include the bivalent carboxylic acid, the standard deviation value was 50 Å or more regardless of the type of the photoresist.

In Comparative Examples 5 and 7 which did not include the second organic solvent, the straightness and uniformity of the EBR line were not observed regardless of the type of the photoresist, and the hump height calculation value was 500 Å or more.

In Comparative Examples 6 and 8 which did not include the first organic solvent, the photosensitive film was applied to the wafer by less than 95% regardless of the type of the photoresist, or there were stains or portions to which the photoresist was not applied. In addition, there were cases where the photosensitive film was applied to the wafer by less than 80%.

What is claimed is:

1. A thinner composition comprising:
a multifunctional carboxylic acid compound;
a first organic solvent having a dielectric constant of 35 or more; and
a second organic solvent having a dielectric constant of less than 35.

2. The thinner composition according to claim 1, wherein the multifunctional carboxylic acid compound comprises a compound to which two or more carboxyl groups are bonded.

3. The thinner composition according to claim 2, wherein the multifunctional carboxylic acid compound comprises a compound to which carboxyl groups are bonded at both ends thereof.

4. The thinner composition according to claim 2, wherein the multifunctional carboxylic acid compound comprises a carboxyl acid compound to which at least one substituent is bonded, and
the substituent comprises at least one selected from the group consisting of a hydroxyl group, a thiol group, a carboxyl group, a primary amine group, an alkylcarbonylamine group having 2 to 10 carbon atoms, an alkoxycarbonylamine group having 2 to 10 carbon atoms and an alkyl group having 1 to 6 carbon atoms.

5. The thinner composition according to claim 4, wherein the substituent comprises a primary amine group or an alkoxycarbonylamine group having 2 to 10 carbon atoms.

6. The thinner composition according to claim 4, wherein the substituent is bonded to a carbon atom to which the carboxyl group is bonded, and the substituent is a primary amine group or an alkoxycarbonylamine group having 2 to 10 carbon atoms.

7. The thinner composition according to claim 1, wherein the multifunctional carboxylic acid compound comprises a compound represented by Formula 1 below: 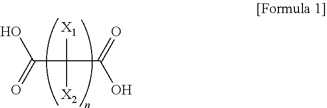
wherein X₁ and X₂ are each independently hydrogen, a hydroxyl group, a thiol group, a carboxyl group, a primary amine group, an alkylcarbonylamine group having 2 to 10 carbon atoms, an alkoxycarbonylamine group having 2 to 10 carbon atoms, an alkyl group having 1 to 6 carbon atoms, or an alkyl group having 1 to 6 carbon atoms and substituted with at least one selected from the group consisting of a hydroxyl group, a thiol group, a primary amine group, a carboxyl group, an aldehyde group, an alkoxy group having 1 to 10 carbon atoms, an alkylcarbonyl group having 2 to 10 carbon atoms, and an alkoxycarbonyl group having 2 to 10 carbon atoms, wherein n is an integer of 1 to 10.

8. The thinner composition according to claim 7, wherein the X₁ and X₂ are each independently selected from the group consisting of hydrogen, a hydroxyl group, and a carboxyl group.

9. The thinner composition according to claim 7, wherein one or more of X₁ and X₂ is a primary amine group, an alkylcarbonylamine group having 2 to 10 carbon atoms, or an alkoxycarbonylamine group having 2 to 10 carbon atoms.

10. The thinner composition according to claim 1, wherein the multifunctional carboxylic acid compound comprises at least one selected from the group consisting of succinic acid, malic acid, citric acid, glutamic acid, and N-(tert-butoxycarbonyl)-L-aspartic acid.

11. The thinner composition according to claim 1, wherein the multifunctional carboxylic acid compound is included in an amount of 0.01 ppm to 100 ppm based on a total weight of the organic solvent including the first organic solvent and the second organic solvent.

12. The thinner composition according to claim 1, wherein the composition does not include a monovalent carboxylic acid compound.

13. The thinner composition according to claim 1, wherein a content of the first organic solvent is a content of the second organic solvent or less based on a total weight of the organic solvent including the first organic solvent and the second organic solvent.

14. The thinner composition according to claim 1, wherein a content of the first organic solvent is 0.5 wt % to 50 wt %, and a content of the second organic solvent is 50 wt % to 99.5 wt %, based on a total weight of the organic solvent including the first organic solvent and the second organic solvent.

15. The thinner composition according to claim 1, wherein the first organic solvent comprises at least one selected from the group consisting of dimethyl sulfate, gamma-buturolactone, ethylene carbonate, propylene carbonate, N,N-dimethylformamide, N,N-diethylformamide and N,N-dimethylacetamide, and
the second organic solvent comprises at least one selected from the group consisting of propylene glycol monoalkyl ether acetate, alkyl 2-hydroxyisobutyrate, propionate, ketone, and pyrrolidone.

16. A substrate processing method comprising:
treating the substrate with the thinner composition according to claim 1; and
after the treating, applying a photoresist to the substrate.

17. A substrate processing method comprising treating a substrate with the thinner composition according to claim 1 before an exposure process after applying a photoresist to the substrate.
